(19) United States
(12) Patent Application Publication
(10) Pub. No.: US 2025/0038022 A1
(43) Pub. Date: Jan. 30, 2025

(54) STATUS DETERMINATION METHOD AND MONITORING DEVICE

(71) Applicant: Tokyo Electron Limited, Tokyo (JP)

(72) Inventors: Huizhen BU, Tokyo (JP); Toshiyuki FUKUMOTO, Yamanashi (JP); Yutai MATSUHASHI, Iwate (JP)

(21) Appl. No.: 18/778,435

(22) Filed: Jul. 19, 2024

(30) Foreign Application Priority Data
Jul. 24, 2023 (JP) 2023-119830

(51) Int. Cl. H01L 21/67; G05B 23/02

(52) U.S. Cl. CPC H01L 21/67276; G05B 23/0221; H01L 21/67248; H01L 21/67288

(57) ABSTRACT

A status determination method includes: (a) acquiring vibration data from a sensor that detects vibration of a vacuum pump provided in a substrate processing apparatus that performs a substrate processing based on a recipe including a plurality of steps, in a specific step among the steps; (b) calculating a vibration change feature amount of a predetermined frequency band from the vibration power spectrum calculated based on the vibration data; (c) calculating, in the specific step, a first divergence degree between a normal vibration feature amount and the vibration change feature amount of the predetermined frequency band based on the vibration data acquired from the sensor that detects the vibration of the vacuum pump at the time of replacement or a brand-new vacuum pump; and (d) outputting a warning about a state of the vacuum pump when the first divergence degree is equal to or greater than a first threshold.

### CROSS-REFERENCE TO RELATED APPLICATIONS

This application is based on and claims priority from Japanese Patent Application No. 2023-119830, filed on Jul. 24, 2023, with the Japan Patent Office, the disclosure of which is incorporated herein in its entirety by reference.

### TECHNICAL FIELD

The present disclosure relates to a status determination method and a monitoring device.

### BACKGROUND

Japanese Patent Laid-Open Publication No. 2021-102817 discloses, in order to improve the accuracy of failure prediction of a semiconductor manufacturing apparatus, acquiring physical quantities of various sensors, calculating feature amounts of a waveform of each sensor value, calculating a degree of divergence and an increase/decrease rate by comparison with normal data, and outputting an alarm when the degree of divergence from the normal data exceeds an upper limit.

International Patent Publication WO 2020/188747 discloses, as a technology for performing predetermined processing on substrates by executing a process recipe including a plurality of steps, determining an indication of abnormality based on vibration data detected by a vibration sensor in a specified step among the steps constituting the process recipe.

### SUMMARY

According to an aspect of the present disclosure, a status determination method includes: (a) acquiring vibration data from a sensor that detects vibration of a vacuum pump provided in a substrate processing apparatus that performs a substrate processing based on a recipe including a plurality of steps, in a specific step among the steps; (b) calculating a vibration power spectrum of a predetermined frequency based on the vibration data, and calculating a vibration change feature amount of a predetermined frequency band from the vibration power spectrum of the predetermined frequency; (c) calculating, in the specific step, a first divergence degree indicating a degree of divergence between a normal vibration feature amount calculated in advance through execution of (b), and the vibration change feature amount of the predetermined frequency band subsequently calculated in (b), based on the vibration data acquired from the sensor that detects the vibration of the vacuum pump at the time of replacement or a brand-new vacuum pump; and (d) outputting a warning about a state of the vacuum pump when the first divergence degree is equal to or greater than a first threshold set in advance.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1 is a schematic cross-sectional view illustrating an example of a substrate processing apparatus according to an embodiment.

FIG. 2 is a configuration diagram illustrating an example of a substrate processing system according to an embodiment.

FIG. 3 is a view illustrating an example of a hardware configuration of a monitoring device according to an embodiment.

FIG. 4 is a view illustrating an example of a functional configuration of the monitoring device according to an embodiment.

FIG. 5 is a flow chart illustrating an example of a status determination method according to an embodiment.

FIG. 6 is a view illustrating an example of abnormality determination processing in S6 of FIG. 5 according to an embodiment.

FIG. 7 is a view illustrating an example of a vibration change rate of an entire frequency band according to an embodiment.

FIG. 8 is a view illustrating an example of a vibration change rate of each frequency band according to an embodiment.

FIGS. 9A and 9B are two-dimensional maps illustrating a vibration power spectrum and a vibration change rate between substrate processings according to an embodiment.

FIG. 10 is a view illustrating an example of the result in the status determination method according to an embodiment.

FIG. 11 is a view illustrating an example of a multivariate abnormality detection model.

### DETAILED DESCRIPTION

In the following detailed description, reference is made to the accompanying drawings, which form a part thereof. The illustrative embodiments described in the detailed description, drawings, and claims are not meant to be limiting. Other embodiments may be utilized, and other changes may be made without departing from the spirit or scope of the subject matter presented here.

Hereinafter, an embodiment of the present disclosure will be described with reference to drawings. In the drawings, same components are denoted by the same reference numerals, and duplicate descriptions are omitted in some cases.

### [Substrate Processing Apparatus]

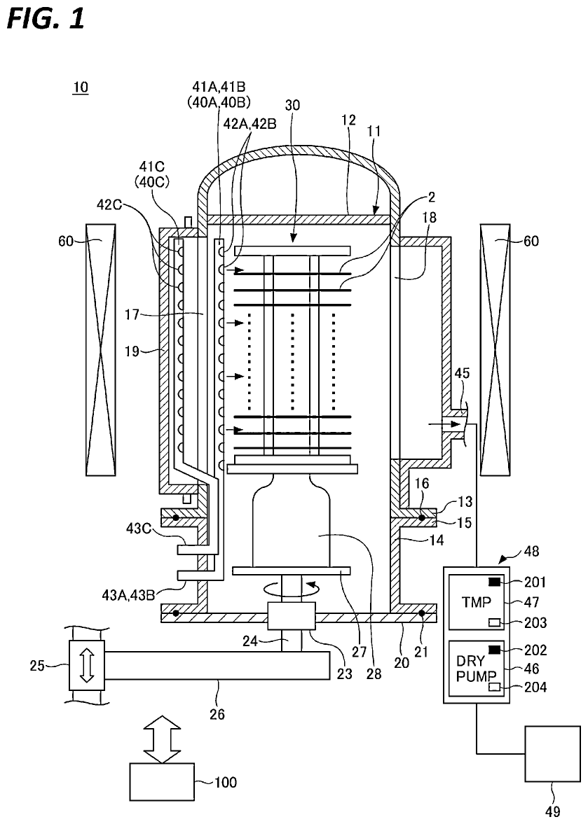

Descriptions will be made on a batch-type substrate processing apparatus that performs a desired film formation processing on a plurality of substrates, with reference to FIG. 1. FIG. 1 is a schematic cross-sectional view illustrating an example of a substrate processing apparatus 10 according to an embodiment. The substrate processing apparatus 10 accommodates a plurality of wafers 2 in a processing container 11, and forms films on the plurality of wafers at the same time. The wafer 2 is an example of a substrate.

The substrate processing apparatus 10 is a vertical batch-type heat treatment apparatus that processes the plurality of wafers 2. The substrate processing apparatus 10 has the processing container 11 that accommodates the wafers 2, a lid 20 that closes the opening in an air tight manner at the lower end of the processing container 11, and a boat 30 that holds the wafers 2. Inside the processing container 11, a space where the wafers 2 are processed is formed. The wafer 2 is, for example, a semiconductor substrate (also simply referred to as a “substrate”), and is, for example, a silicon wafer.

The processing container 11 has a cylindrical processing-container body 12 with an open lower end and a ceiling. The body 12 of the processing container is made of, for example, quartz. A flange 13 is formed at the lower end of the body 12 of the processing container. Also, the processing container 11 has, for example, a cylindrical manifold 14. The manifold 14 is made of, for example, stainless steel. A flange 15 is formed at the upper end of the manifold 14, and the flange 13 of the body 12 of the processing container is installed at the flange 15. A sealing member 16 such as an O ring is disposed between the flange 15 and the flange 13.

The lid 20 is attached to the opening in an air tight manner at the lower end of the manifold 14 via a sealing member 21 such as an O ring. The lid 20 is made of, for example, stainless steel. A through hole that vertically passes through the lid 20 is formed in the center of the lid 20. A rotating shaft 24 is disposed in the through hole. A gap between the lid 20 and the rotating shaft 24 is sealed by a magnetic fluid sealing portion 23. The lower end of the rotating shaft 24 is rotatably supported by an arm 26 of an elevating portion 25. A rotary plate 27 is provided at the upper end of the rotating shaft 24. The boat 30 is installed on the rotary plate 27 via a heat retention table 28.

The boat 30 holds the plurality of wafers 2 in the vertical direction. For example, in the boat 30 capable of holding 200 wafers 2, slots to which slot numbers 1 to 200 are given are arranged in the vertical direction. The wafer 2 is disposed in each slot, and then the wafers 2 are individually horizontally held at intervals. The boat 30 is made of, for example, quartz (SiO₂) or silicon carbide (SIC). When the elevating portion 25 is raised, the lid 20 and the boat 30 are raised, and the boat 30 is carried into the processing container 11. Then, the opening at the lower end of the processing container 11 is sealed by the lid 20. When the elevating portion 25 is lowered, the lid 20 and the boat 30 are lowered, and the boat 30 is carried to the outside of the processing container 11. Also, when the rotating shaft 24 is rotated, the boat 30 rotates together with the rotary plate 27.

The substrate processing apparatus 10 has three gas supply pipes 40A, 40B, and 40C. The gas supply pipes 40A, 40B, and 40C are made of, for example, quartz (SiO₂). The gas supply pipes 40A, 40B, and 40C supply gases into the processing container 11. The types of gases will be described below. One gas supply pipe may discharge one type of gas or a plurality of types of gases in sequence. Also, a plurality of gas supply pipes may discharge the same type of gas.

The gas supply pipes 40A, 40B, and 40C have horizontal pipes 43A, 43B, and 43C that horizontally pass through the manifold 14, and vertical pipes 41A, 41B, and 41C that are vertically disposed inside the processing container 11. The vertical pipes 41A, 41B, and 41C have a plurality of air supply ports 42A, 42B, and 42C at intervals in the vertical direction. Various gases supplied to the horizontal pipes 43A, 43B, and 43C are sent to the vertical pipes 41A, 41B, and 41C, and are horizontally discharged from the plurality of air supply ports 42A, 42B, and 42C. The vertical pipe 41C is disposed within a plasma box 19. The vertical pipes 41A and 41B are disposed within the processing container 11.

The substrate processing apparatus 10 has an exhaust pipe 45. The exhaust pipe 45 is connected to an exhaust device 48. The exhaust device 48 includes a vacuum pump, and exhausts the inside of the processing container 11. In FIG. 1, the exhaust device 48 has a dry pump 46 and a turbo molecular pump (TMP) 47 as vacuum pumps. The dry pump 46 roughly exhausts the inside of the processing container 11, and the TMP 47 further evacuates the inside of the processing container 11 for which rough exhaustion has been performed.

An exhaust port 18 is formed on the body 12 of the processing container in order to exhaust the inside of the processing container 11. The exhaust port 18 is disposed to face the air supply ports 42A, 42B, and 42C. Gases horizontally discharged from the air supply ports 42A, 42B, and 42C are exhausted from the exhaust pipe 45 after passing through the exhaust port 18. The exhaust device 48 sucks the gas inside the processing container 11 and sends the gas to a detoxifying apparatus 49. The detoxifying apparatus 49 removes harmful components of exhaust gas and then releases the exhaust gas to the atmosphere.

The substrate processing apparatus 10 further includes a heating unit 60. The heating unit 60 is disposed outside the processing container 11, and heats the inside of the processing container 11 from the outside of the processing container 11. For example, the heating unit 60 is formed in a cylindrical shape so as to surround the body 12 of the processing container. The heating unit 60 is constituted by, for example, a heater. The heating unit 60 heats the inside of the processing container 11 so as to improve the processing capacity of gas supplied into the processing container 11.

An opening 17 is formed in a part in the circumferential direction of the body 12 of the processing container. The plasma box 19 is formed on the side surface of the processing container 11 so as to surround the opening 17. The plasma box 19 is formed to protrude outwards in the radial direction from the body 12 of the processing container, and is formed in a U shape when viewed in, for example, the vertical direction.

A pair of electrodes is arranged such that the plasma box 19 is interposed between the electrodes. The couple of electrodes are a couple of parallel electrodes which are installed on the outside of the plasma box 19 and face each other. Like the vertical pipe 41C, the couple of electrodes are formed in vertically elongated shapes while facing each other. The couple of electrodes are connected to an RF power supply via a matching unit, and a high frequency voltage is applied from the RF power supply.

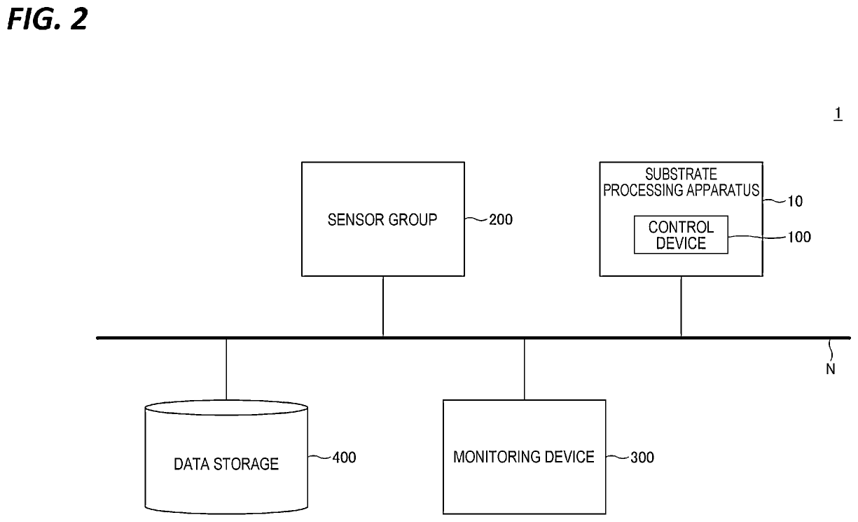

The substrate processing apparatus 10 includes a control device 100. The control device 100 processes computer-executable instructions that cause the substrate processing apparatus 10 to execute various steps for substrate processing. The control device 100 may be configured to control each element of the substrate processing apparatus 10 so as to execute various steps for substrate processing. In an embodiment, the control device 100 may be included in whole or in part in the substrate processing apparatus 10. The control device 100 may include a processor, a data storage and a communication interface. The control device 100 is implemented by, for example, a computer. The processor may be configured to read a recipe and a program from the data storage, and to execute the read recipe and program so as to perform various control operations. The recipe and the program may be stored in the data storage in advance, or may be acquired via a medium if necessary. The medium may be various storage media readable by the computer, or may be a communication line connected to the communication interface. The processor may be a central processing unit (CPU). The data storage may be a RAM, a ROM, a HDD, etc. The communication interface may perform communication between the substrate processing apparatus 10, a sensor group 200, and a monitoring device 300 (see, e.g., FIG. 2) via a communication network such as a local area network (LAN).

### [Substrate Processing System]

Next, a substrate processing system 1 will be described with reference to FIG. 2. FIG. 2 is a configuration diagram illustrating an example of the substrate processing system 1 according to an embodiment. The substrate processing system 1 includes the substrate processing apparatus 10, the sensor group 200, the monitoring device 300 and a data storage 400. These devices are connected such that data communication is possible via a communication network (N) such as the Internet or a LAN. The control device 100 is incorporated in the substrate processing apparatus 10. Although one substrate processing apparatus is illustrated, two or more may be provided.

A plurality of sensors is attached to the substrate processing apparatus 10. The sensor group 200 attached to the substrate processing apparatus 10 includes a film thickness sensor, a temperature sensor, a humidity sensor, a pressure sensor, a vibration sensor, a distance sensor, etc. In the present embodiment, as illustrated in FIG. 1, a vibration sensor 201 and a temperature sensor 203 are attached near the TMP 47 or near a motor that drives the TMP 47. Also, a vibration sensor 202 and a temperature sensor 204 are attached near the dry pump 46 or near a motor that drives the dry pump 46.

As illustrated in FIG. 1, the substrate processing apparatus 10 carries the boat 30 on which the plurality of wafers 2 is placed, into the processing container 11, and performs film formation on the plurality of wafers 2. After the boat 30 is carried into the processing container 11, the wafers 2 are simultaneously subjected to a film formation process, and then, the boat 30 inside the processing container 11 is carried to the outside. Performing a predetermined process such as film formation on the wafers 2, through a series of processes, is called “substrate processing.” A substrate processing number is given so as to identify substrate processing performed each time the boat 30 is carried into the processing container 11. That is, the substrate processing number is an identification number of substrate processing.

The log data of the sensor values measured by the sensor group 200 is time-series data, and is stored in the data storage 400. The monitoring device 300 acquires necessary log data from the data storage 400, and determines the states of vacuum pumps of the exhaust device 48 (the dry pump 46 and the TMP 47). In the present embodiment, the monitoring device 300 acquires vibration data detected by the vibration sensors 201 and 202, and temperature data detected by the temperature sensors 203 and 204, from the data storage 400.

When the film formation is repeated, by-products are accumulated inside the vacuum pump. If the accumulation amount of by-products increases, the vacuum pump breaks down and makes an urgent stop, leading to a decrease in productivity of the substrate processing apparatus 10. Also, if the accumulation amount of by-products increases, the vibration of the vacuum pump increases. Therefore, it is desirable to detect the vibration state of the vacuum pump, and to predict abnormality of the vacuum pump in advance before the vacuum pump is stopped due to, for example, a breakdown, so that countermeasures such as maintenance of the vacuum pump may be taken in advance.

Here, in a conventional abnormality detection method, vibration data is acquired in a specified step in a process recipe, and a normal model is created using a feature amount such as an amplitude value of a vibration frequency spectrum in a predetermined frequency band at a normal time. Then, for the vibration data, a divergence degree between the feature amount in the predetermined frequency band and the normal model is calculated. The divergence degree exceeding a predetermined threshold is determined as a predictive sign of abnormality.

However, the vibration of the vacuum pump is different for each step in a recipe including a plurality of steps. The state of the vibration of the vacuum pump is also changed when the substrate processing apparatus 10 is stopped or the substrate processing apparatus 10 is subjected to maintenance. For example, in some cases, the vibration of the vacuum pump may be abnormal for a while, after a long idle time subsequent to restarting of the substrate processing apparatus 10. Therefore, in a conventional method, depending on the selection of a specified step in the recipe, a variation is caused in the vibration of the vacuum pump, making it difficult to perform high-accuracy monitoring.

Also, since the normal region of the normal model is determined by statistics such as the amplitude of the predetermined frequency in the normal state, characteristics of the amplitude of the normal state have a large influence on the normal model, and the monitoring accuracy of the vacuum pump is easily affected by learning results of the normal model.

Also, in the conventional method, since the vibration is observed only by some feature amounts [fixed frequency, N-th harmonic, root mean square (RMS), etc.], it is difficult to grasp the change of the vibration over time in the entire frequency band. When an abnormality judgment model is created by the sum of the amplitude of a predetermined frequency and the amplitude of any frequency range, since in the calculation of the sum for the frequency ranges, the addition of a frequency of an increase of an amplitude and a frequency of a decrease approaches 0 in the calculation, the effect of the fluctuation may not appear in the addition result in some cases. Then, the vibration change of the frequency range cannot be accurately expressed.

Also, the conventional method does not monitor the fluctuation between substrate processings, and thus cannot determine a large change between substrate processings, as a predictive sign of abnormality of the vacuum pump. The vibration of the vacuum pump also changes when the temperature of the vacuum pump drops due to the stopping of the substrate processing apparatus 10 or the maintenance of the substrate processing apparatus 10. When it is determined that there is a predictive sign of abnormality of the vacuum pump in a case where both the temperature sensor and the vibration sensor indicate abnormality, even if the vacuum pump is normal, there are cases where the vacuum pump is deemed to be abnormal due to the influence caused by the maintenance of the substrate processing apparatus 10.

Therefore, in the present embodiment, a vibration power spectrum (vibration power intensity) of a predetermined frequency is calculated based on vibration data, and then, a vibration change feature amount of a predetermined frequency band is calculated from the vibration power spectrum of the predetermined frequency. Then, a first divergence degree is calculated, which indicates the degree of divergence between a normal vibration feature amount calculated based on vibration data acquired from a sensor that detects the vibration of the vacuum pump at the time of replacement or a brand-new vacuum pump, and a vibration change feature amount of a predetermined frequency band calculated from vibration data detected during subsequent substrate processing. Then, if the first divergence degree is equal to or greater than a preset first threshold, it is determined that there is a predictive sign of abnormality of the vacuum pump, and a warning is output.

Also, the abnormality of the vacuum pump and the predictive sign of abnormality are determined based on the vibration data remaining after exclusion of the vibration data corresponding to temperature data falling outside a preset temperature range in the temperature data.

### [Hardware Configuration]

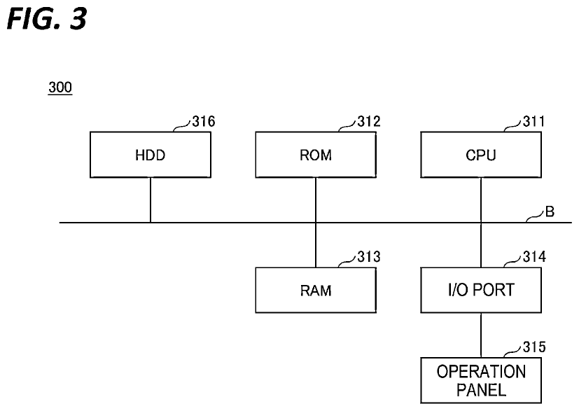

The monitoring device 300 is realized by, for example, a computer having a hardware configuration illustrated in FIG. 3. FIG. 3 is a view illustrating an example of the hardware configuration of the monitoring device 300 according to an embodiment. The monitoring device 300 is implemented by, for example, a computer, and includes a central processing unit (CPU) 311, a read only memory (ROM) 312, and a random access memory (RAM) 313. Also, the monitoring device 300 includes an input/output (I/O) port 314, an operation panel 315, and a hard disk drive (HDD) 316. Individual parts are connected by a bus B.

The CPU 311 is an arithmetic device that reads programs or data, on the RAM 313, from a storage device such as the ROM 312 or the HDD 316, and executes substrate processing, thereby realizing the overall control or functions of the monitoring device 300.

The ROM 312 is a storage medium that is constituted by an electrically erasable programmable ROM (EEPROM), a flash memory, a hard disk, etc., and stores programs to be used by the CPU 311. The RAM 313 functions as, for example, a work area of the CPU 311. The programs used by the CPU 311 include a program for executing a display method, which is described below.

The I/O port 314 acquires measurement values measured by the sensor group 200, such as vibration data and temperature data, and transmits the values to the CPU 311. The operation panel 315 through which the user operates the monitoring device 300 is connected to the I/O port 314.

The HDD 316 is an auxiliary storage device, and may store programs, etc. The HDD 316 may also store log data measured by the sensor group 200.

### [Functional Configuration]

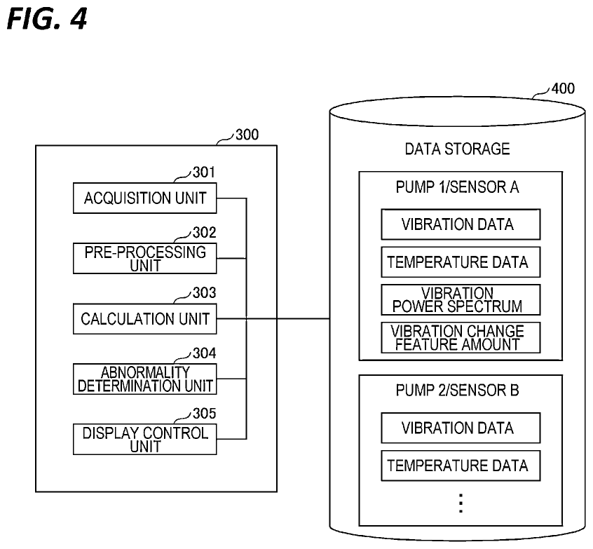

Next, the functional configuration of the monitoring device 300 will be described with reference to FIG. 4. FIG. 4 illustrates an example of a functional configuration of the monitoring device 300 according to an embodiment. The monitoring device 300 determines the states of the vacuum pumps included in the substrate processing apparatus 10, i.e., the dry pump 46 and the TMP 47.

The monitoring device 300 includes an acquisition unit 301, a pre-processing unit 302, a calculator 303, an abnormality determination unit 304 and a display controller 305. The acquisition unit 301 acquires vibration data detected by the vibration sensor provided near the vacuum pump of the substrate processing apparatus 10 and temperature data detected by the temperature sensor in a specific step among steps of a recipe used by the substrate processing apparatus 10 in substrate processing. Vibration data and temperature data may be time-series data. The acquisition unit 301 stores vibration data and temperature data for each vacuum pump and each sensor, in the data storage 400 (see FIG. 4).

In the present embodiment, the specific steps are a step during which the vacuum pump is idle, and a step of reducing the pressure of the processing container 11 from the atmospheric pressure to a predetermined pressure. Meanwhile, the specific steps are not limited to these, and steps during which the vacuum pump operates under approximately the same conditions are specified. In order not to overlook an abnormality signal of the vacuum pump, it is desirable to acquire vibration data from both the step with the highest load of the vacuum pump (e.g., the decompression step in the processing container) and the step with the lowest load of the vacuum pump (the step during which the vacuum pump is in an idle state).

In the specific step, the pre-processing unit 302 excludes vibration data corresponding to temperature data falling outside a preset temperature range in the temperature data acquired together with the vibration data, and calculates a vibration power spectrum of a predetermined frequency based on vibration data remaining after the exclusion. The pre-processing unit 302 calculates a vibration change feature amount of a predetermined frequency band from the calculated vibration power spectrum of the predetermined frequency. The pre-processing unit 302 stores the calculated vibration power spectrum of the predetermined frequency and the calculated vibration change feature amount of the predetermined frequency band, for each vacuum pump and each sensor, in the data storage 400 (see FIG. 4).

In the specific step, the calculator 303 learns a normal vibration feature amount based on vibration data acquired from a sensor that detects the vibration of the vacuum pump at the time of replacement or a brand-new vacuum pump. After that, in the specific step, the calculator 303 calculates the vibration change feature amount of the predetermined frequency band based on vibration data acquired from the vibration sensor, and calculates a first divergence degree indicating the degree of divergence from the normal vibration feature amount.

The vacuum pump at the time of replacement is not limited to when the whole vacuum pump disposed in the substrate processing apparatus 10 is replaced, and also includes, for example, replacement of a trap attached to the vacuum pump, replacement of a vacuum pump oil, etc. Meanwhile, for example, in realizing replacement of a trap, it is possible to perform the monitoring of the vibration by the monitoring device 300 in the same manner as in the vacuum pump, by attaching a vibration sensor to a trap itself.

The abnormality determination unit 304 determines whether the first divergence degree is equal to or greater than a preset first threshold. When it is determined that the first divergence degree is equal to or greater than the first threshold, the abnormality determination unit 304 determines that there is a predictive sign of abnormality in the vacuum pump, and thus, the display controller 305 outputs a warning about the vacuum pump. Even after the output of the warning, substrate processing is continued, and the vacuum pump is also not stopped. This allows a user to perform, for example, replacement of a vacuum pump, as a countermeasure to the output of the warning, in a timely manner.

The acquisition unit 301 is realized by, for example, the operation panel 315 and the I/O port 314. The pre-processing unit 302, the calculator 303, the abnormality determination unit 304, and the display controller 305 are implemented by, for example the CPU 311. The data storage 400 may be disposed inside the monitoring device 300, and in that case, is realized by, for example, the ROM 312, the RAM 313, and the HDD 316.

### [Status Determination Method]

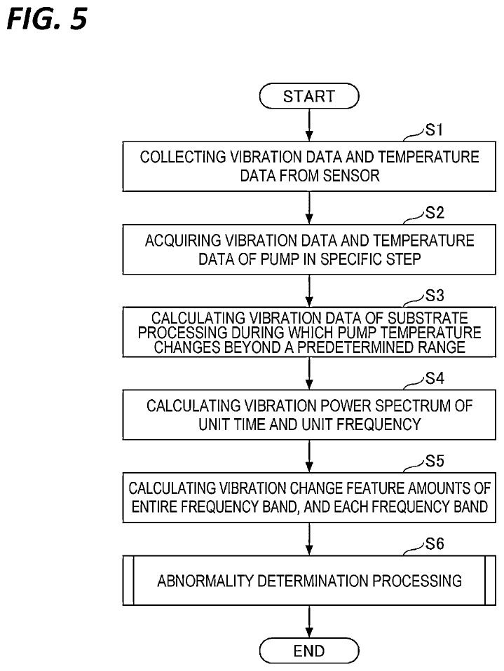

Next, an example of a status determination method according to an embodiment will be described with reference to FIG. 5. FIG. 5 is a flow chart illustrating an example of a status determination method according to an embodiment.

The substrate processing apparatus 10 executes substrate processing based on a recipe including a plurality of steps. A vibration sensor near a vacuum pump detects vibrations through, for example, the rotation of a motor that drives the vacuum pump during the substrate processing. The status determination method according to the present embodiment is executed by the monitoring device 300, and the monitoring device 300 determines the state of the vacuum pump based on vibration data detected by the vibration sensor.

First, in the step S1, the acquisition unit 301 collects vibration data detected by the vibration sensor provided near the vacuum pump and temperature data detected by the temperature sensor during substrate processing.

Next, in the step S2, the acquisition unit 301 acquires vibration data and temperature data of the vacuum pump, for a specific step among steps included in the recipe, from the collected vibration data and temperature data. For example, the specific steps may be a step during which the vacuum pump is idle, and a step of reducing the pressure of the processing container 11 where substrates are processed, from the atmospheric pressure to a predetermined pressure.

Next, in the step S3, the pre-processing unit 302 determines whether any of the acquired temperature data falls outside a preset temperature range. When it is determined that there is temperature data falling outside the preset temperature range, the pre-processing unit 302 excludes vibration data corresponding to the temperature data, from target vibration data to be used for determining a predictive sign of abnormality of the vacuum pump. Accordingly, when the temperature of the vacuum pump is changed due to reasons such as a case where the substrate processing apparatus 10 is stopped, vibration data containing lots of noise may be excluded from analysis target vibration data. Thus, it is possible to improve the accuracy in determining the predictive sign of abnormality of the vacuum pump.

Next, in the step S4, the pre-processing unit 302 calculates a vibration power spectrum (vibration power intensity) of a unit time and a unit frequency based on the vibration data remaining after the exclusion. The unit time may be set as an arbitrary time by the user, or can be automatically set. The unit frequency may be set as an arbitrary frequency by the user, or can be automatically set.

Next, in the step S5, the calculator 303 calculates a vibration change feature amount of the entire frequency band, and a vibration change feature amount of a predetermined frequency band, based on the vibration power spectrum of the unit time and the unit frequency.

The step S4 and the step S5 are an example of processing in which a vibration change rate of a predetermined frequency band is calculated based on vibration data, and a vibration change feature amount of the predetermined frequency band is calculated from the vibration change rate of the predetermined frequency band.

In this step, the vibration change feature amount of the predetermined frequency band includes the vibration change feature amount of the entire frequency band, and the vibration change feature amount of each frequency band obtained when the entire frequency band is divided into multiple frequency bands.

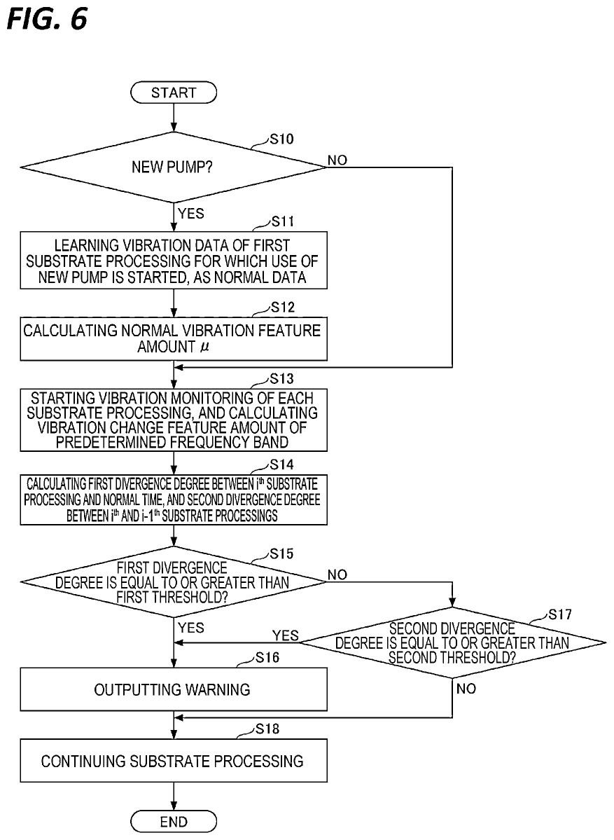

Next, in the step S6, the abnormality determination unit 304 executes abnormality determination processing. The abnormality determination processing will be described in detail with reference to FIG. 6.

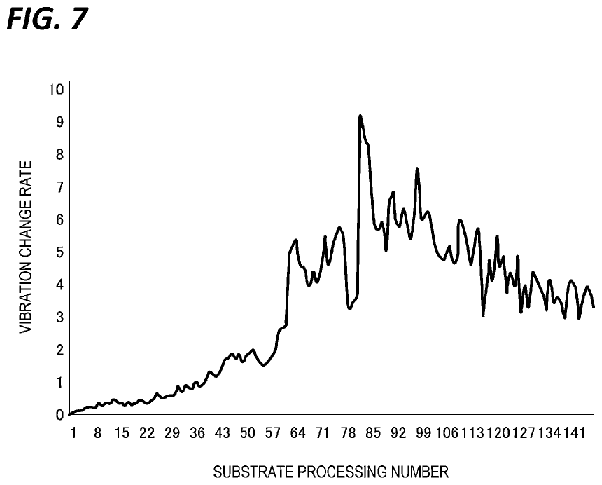

FIG. 7 is a view illustrating an example of a vibration change rate of an entire frequency band according to an embodiment. The horizontal axis of FIG. 7 indicates a substrate processing number which is a substrate processing identification number given to every processing for the plurality of wafers 2 held by the boat 30. The vertical axis indicates a vibration change rate of an entire frequency band for every substrate processing. The vibration change rate is an example of a vibration change feature amount. The entire frequency band is 0 to 10000 Hz. Meanwhile, the entire frequency band is not limited to this, but may be a frequency range at which the vibration sensor can perform measurement at a predetermined sampling rate.

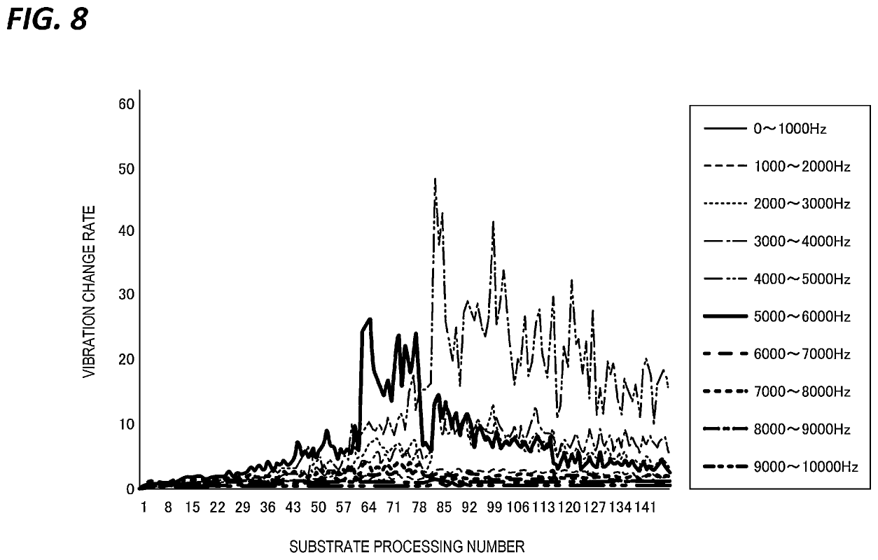

FIG. 8 is a view illustrating an example of a vibration change rate of each frequency band according to an embodiment. The horizontal axis of FIG. 8 indicates a substrate processing number, and the vertical axis indicates a vibration change rate of each frequency band for every substrate processing. Each frequency band is obtained when the vibration change rate of the entire frequency band is divided into multiple frequency bands. Each frequency band is divided at every 1000 Hz.

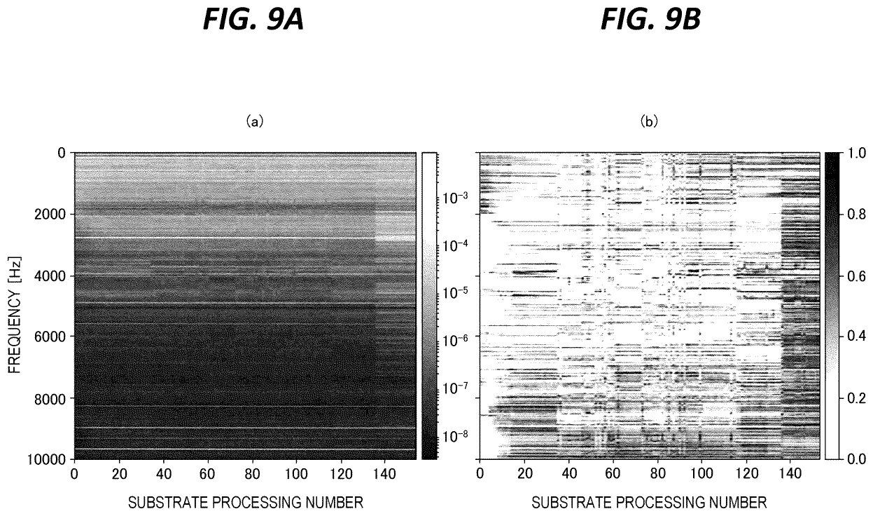

FIG. 9A is a two-dimensional map illustrating a vibration power spectrum according to an embodiment, and FIG. 9B is a two-dimensional map illustrating a vibration change rate according to an embodiment.

The vibration power spectrum of a predetermined frequency band is divided into vibration power spectra of unit frequencies for each substrate processing. Then, the separate vibration power spectra are visualized and displayed on the two-dimensional map illustrated in FIG. 9A. The two-dimensional map has a unit frequency and a substrate processing number (an identification number for substrate processing) as two axes.

For example, in the step S4, the calculated vibration power spectrum (vibration power intensity) of the unit time and the unit frequency may be visualized and displayed on the two-dimensional map by changing the color or shading. The waveform of the vibration power spectrum of the unit time and the unit frequency may be visualized by colors or shading so as to be shown to the user.

Also, vibration change rates calculated from separate vibration power spectra are visualized and displayed on the two-dimensional map illustrated in FIG. 9B. The two-dimensional map has a value corresponding to a unit frequency and a substrate processing number (an identification number for substrate processing) as two axes. Accordingly, vibration change rates between substrate processings indicated by substrate processing numbers on the horizontal axis may be visualized by colors or shading so as to be shown to the user.

FIG. 9B illustrates a vibration change rate between substrate processings, which is normalized in a range of 0 to 1, as an example of the value corresponding to the unit frequency on the vertical axis. Here, for each frequency, vibration power spectra of all substrate processings are normalized in a range of 0 to 1, which are visualized as vibration change rates between substrate processings and then are displayed. This makes it easier for the user to see the vibration change rates between substrate processings.

Through the two-dimensional maps of FIGS. 9A and 9B, vibration power spectra and vibration change rates in the entire frequency band may be visualized, allowing the user to easily grasp the vibration state of the vacuum pump.

### (Abnormality Determination Processing)

Next, descriptions will be made on details of abnormality determination processing in FIG. 6. The abnormality determination processing is called when the step S6 of FIG. 5 is executed. In the abnormality determination processing, in the step S10, the calculator 303 determines whether a new vacuum pump has been installed. A new vacuum pump is a brand-new vacuum pump or a vacuum pump immediately after replacement. When the calculator 303 determines that there is a new vacuum pump, the process proceeds to step S11. When the calculator 303 determines that there is no new vacuum pump, the process proceeds to step S13.

In the step S11, the calculator 303 learns vibration data of first substrate processing for which the use of the new vacuum pump is started, as normal data. The “vibration data of first substrate processing” referred to here may not only be vibration data of the first substrate processing using the new vacuum pump, but also vibration data of n (1th to nth (n is a positive integer)) substrate processings using the new vacuum pump.

Next, in the step S12, the calculator 303 calculates a normal vibration feature amount u by Formula (1). When the normal vibration feature amount u is calculated by using the vibration data of n substrate processings using the new vacuum pump, the normal vibration feature amount u is an average value of normal vibration feature amounts.

$${μ}_{j} = {\sum }_{i = 0}^{n} {P}_{i , j} / n \qquad ( 1 )$$

Here, i is a substrate processing number, j is a frequency, and P_{i,j} is a vibration power spectrum of the i^{th} substrate processing (substrate processing number i) at a frequency j (Hz). n is a numerical value of a substrate processing number whose vibration data is learned as data for a normal time, since the first substrate processing number (1) for which the use of the new vacuum pump is started. For example, n is set as 5 when vibration data of five substrate processings (from the substrate processing number (1) for which the use of the new vacuum pump is started to the substrate processing number (5)) is learned as normal data. n may be set by the user.

Next, in the step S13, the calculator 303 starts vibration monitoring of each substrate processing since the (n+1)^{th} processing, and calculates the vibration power spectrum P_{i,j} of each substrate processing i at each frequency j. When vibration data for 1 st to 5th substrate processings is learned as normal data, the substrate processing number i in the step S13 starts from 6.

Next, in the step S14, the calculator 303 calculates a vibration change rate. The calculator 303 calculates a vibration change rate θ_{i,j} of the i^{th} substrate processing at a frequency j through Formula (2) by using a normal vibration feature amount μⱼ at the frequency j, and a vibration power spectrum P_{i,j} of the i^{th} substrate processing (i>n) at the frequency j.

$${θ}_{i , j} = ( {P}_{i , j} - {μ}_{j} ) / {μ}_{j} + 1 \qquad ( 2 )$$

Next, the calculator 303 calculates a vibration change feature amount Q for the i^{th} substrate processing, in a predetermined frequency band (a to b Hz) by using the vibration change rate θ_{i,j}. The vibration change feature amount Q for the i^{th} processing in the predetermined frequency band (a to b Hz) is illustrated below. In addition, a vibration change feature amount Q′ for the i^{th} processing in the predetermined frequency band (a to b Hz) may be calculated.

$$Q = {\sum }_{j = a}^{b} {θ}_{i , j} / j \\ {Q}^{′} = {\sum }_{j = a}^{b} \vert {θ}_{i , j} \vert / j$$

The calculator 303 calculates a difference between the normal vibration feature amount μ and the vibration change feature amount Q, as a first divergence degree. Alternatively, the calculator 303 may calculate a difference between the normal vibration feature amount u and the vibration change feature amount Q′, as a first divergence degree.

It is desirable that the vibration change feature amount Q′ is also calculated in consideration of a case where if the vibration change feature amount Q is calculated as the sum including positive and negative values, the final result becomes 0 and thus no vibration change is occurring.

Also, the calculator 303 may calculate, as a second divergence degree, a difference value between a vibration power spectrum PS_{c} for the i^{th} substrate processing (which is a present substrate processing) at the frequency j in the predetermined frequency band, and a vibration power spectrum PS_{b} for the (i−1)^{th} substrate processing (which is a previous substrate processing) at the frequency j in the predetermined frequency band. The vibration power spectrum PS_{c} for the i^{th} processing in the predetermined frequency band (a to b Hz) is illustrated below.

$${PS}_{c} = {\sum }_{j = a}^{b} {P}_{i , j}$$

The vibration power spectrum PS_{b} for the (i−1)^{th} processing in the predetermined frequency band (a to b Hz) is illustrated below.

$${PS}_{b} = {\sum }_{j = a}^{b} {P}_{i - 1 , j}$$

Next, in the step S15, the abnormality determination unit 304 determines whether the first divergence degree is equal to or greater than a preset first threshold. When it is determined that the first divergence degree is equal to or greater than the first threshold, the abnormality determination unit 304 determines that the state of the vacuum pump indicates a predictive sign of abnormality.

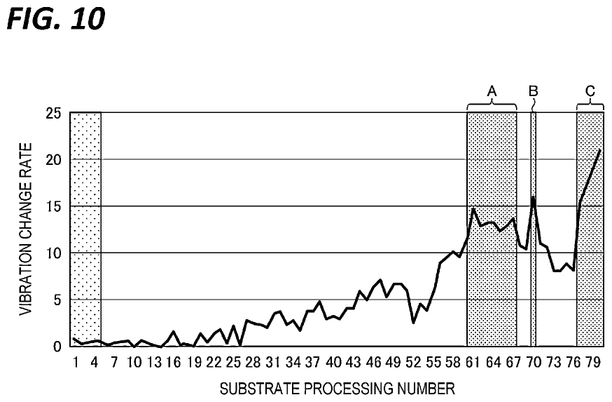

Accordingly, in the step S16, the display controller 305 outputs a warning about the state of the vacuum pump, and in the step S18, causes the control device 100 to continue substrate processing, and ends this processing. In the example of FIG. 10, the horizontal axis is a substrate processing number (an identification number of substrate processing), and the vertical axis is a vibration change rate. Vibration data during substrate processings with substrate processing numbers 1 to 5 was learned as normal data. At the substrate processing numbers 61 to 67, and 76 to 79, the first divergence degree is equal to or greater than the first threshold, and a warning is output.

In the step S15, when it is determined that the first divergence degree is less than the first threshold, the abnormality determination unit 304 proceeds to step S17 and determines whether the second divergence degree is equal to or greater than a preset second threshold. When it is determined that the second divergence degree is equal to or greater than the second threshold, the abnormality determination unit 304 determines that the state of the vacuum pump indicates a predictive sign of abnormality.

Accordingly, in the step S16, the display controller 305 outputs a warning about the state of the vacuum pump, and in the step S18, causes the control device 100 to continue substrate processing, and ends this processing. In the example of FIG. 10, at the substrate processing number 70, the second divergence degree is equal to or greater than the second threshold, and a warning is output.

Also, in the step S17, when it is determined that the second divergence degree is less than the second threshold, the abnormality determination unit 304 causes the control device 100 to continue substrate processing in that state, and ends this processing.

It is desirable that a plurality of first divergence degrees is calculated in the step S14. For example, the calculator 303 may calculate a first divergence degree of the entire frequency band, which indicates a degree of divergence between a normal vibration feature amount of the entire frequency band calculated in advance, and a vibration change feature amount of the entire frequency band calculated for each substrate processing subsequent to learning for the normal time. In addition, the calculator 303 may calculate a first divergence degree of each frequency band, which indicates a degree of divergence between a normal vibration feature amount of each frequency band calculated in advance, and a vibration change feature amount of each frequency band calculated for each substrate processing subsequent to learning for the normal time.

In this case, the abnormality determination unit 304 determines that the state of the vacuum pump indicates a predictive sign of abnormality in at least one of a case where the first divergence degree of the entire frequency band is equal to or greater than a preset first threshold for the entire frequency band, and a case where the first divergence degree of each frequency band is equal to or greater than a preset first threshold for each frequency band. Accordingly, the display controller 305 outputs a warning about the state of the vacuum pump.

It is desirable that a plurality of second divergence degrees is calculated in the step S14. For example, the calculator 303 may calculate a second divergence degree of the entire frequency band, which indicates a difference value (degree of divergence) between a vibration power spectrum of the entire frequency band calculated based on vibration data acquired when the substrate processing apparatus 10 processed the previous substrate and a vibration power spectrum of the entire frequency band calculated based on vibration data acquired when the substrate processing apparatus 10 processed the present substrate. In addition, the calculator 303 may calculate a second divergence degree of each separate predetermined frequency band obtained when the entire frequency band is divided into multiple frequency bands. The second divergence degree indicates a difference value (degree of divergence) between a vibration power spectrum of each separate predetermined frequency band, which is based on vibration data acquired when the substrate processing apparatus 10 processed the previous substrate, and a vibration power spectrum of each separate predetermined frequency band, which is based on vibration data acquired when the substrate processing apparatus 10 processed the present substrate.

In this case, the abnormality determination unit 304 determines that the state of the vacuum pump indicates a predictive sign of abnormality in at least one of a case where the second divergence degree of the entire frequency band is equal to or greater than a preset second threshold for the entire frequency band, and a case where the second divergence degree of each separate predetermined frequency band is equal to or greater than a preset second threshold for each frequency band. Accordingly, the display controller 305 outputs a warning about the state of the vacuum pump.

As the amount of accumulated by-products increases, the vibration of the vacuum pump increases due to the influence. The vibration significantly increases especially before the vacuum pump breaks down. Therefore, in the status determination method according to the present embodiment, a vibration change rate (vibration change feature amount) in each frequency range is observed, so that an early predictive sign of the vacuum pump failure may be found, and then, prior to the failure, the maintenance of the vacuum pump may be performed in advance.

Also, the vibration data is monitored in both the step of reducing the pressure of the processing container 11 from the atmospheric pressure to a predetermined pressure, and the step during which the vacuum pump is in an idle state. Accordingly, it is possible to accurately determine a predictive sign of abnormality of the vacuum pump without overlooking the predictive sign of abnormality, while reducing the number of samples of the vibration data.

In a conventional method, a normal model is created based on a physical feature amount such as an amplitude of vibration data. Meanwhile, in the status determination method according to the present embodiment, the state of the vacuum pump is determined based on a change amount of a physical feature amount of vibration intensity based on the vibration data, specifically, a vibration change feature amount. Accordingly, it is possible to reduce the influence of the amplitude-specific size or characteristics, on a model. This makes it possible to accurately determine a predictive sign of abnormality of the vacuum pump, thereby outputting a warning.

Also, when temperature data acquired at the same timing as the vibration data deviates from temperatures within a normal range, the corresponding vibration data is excluded. Accordingly, vibration data containing noise of vibration abnormality caused by a temperature change may be excluded from analysis target vibration data, and thus, a false warning report about abnormality may be reduced.

Through the output of the warning, the user may take some measures before the vacuum pump breaks down, such as replacing the vacuum pump, removing deposits attached to the vacuum pump by supplying cleaning gas, and changing oil in the vacuum pump.

The user may check whether the warning is about the TMP 47 or the dry pump 46 from the location of the vibration sensor that detects the vibration data.

Also, it is possible to visualize the vibration power spectrum of the predetermined frequency band and the vibration change feature amount of the predetermined frequency band.

### [Others]

In the status determination method according to the present embodiment, in monitoring the vibration of a predetermined frequency band, the first divergence degree based on the vibration change feature amount of all frequencies, and the first divergence degree based on the vibration change feature amount of the predetermined frequency are calculated.

Here, as a method of calculating the vibration change rate (vibration change feature amount), a method using a uniaxial acceleration sensor may be mentioned, in which a frequency band is divided into several bands, and the vibration change rate is calculated for each frequency band. In another method, a feature amount may be automatically extracted by an Auto Encoder (AE) sensor in an ultra-high frequency band.

In addition to calculation of the first divergence degree and the second divergence degree, the maximum value max (θ_{i,j}), the minimum value min (θ_{i,j}), and the standard deviation std (θ_{i,j}) of the vibration change feature amount of the predetermined frequency band may be calculated. It is possible to more accurately determine the predictive sign of abnormality of the vacuum pump through a combination of these statistical values including the first divergence degree and the second divergence degree.

The predetermined frequency band may be defined by the user. As an example of the predetermined frequency band, the 1000 Hz unit in FIG. 8 may be mentioned.

As described above, according to the status determination method and the monitoring device of the present embodiment, it is possible to accurately determine a predictive sign of abnormality of the vacuum pump.

### Modified Example 1

If there is data on the power (pump power) of the vacuum pump in the analysis target step, or if the time until the power of the vacuum pump is stabilized is known in the analysis target step, the vibration intensity when the power of the vacuum pump is stable may be used to monitor and predict the abnormality of the above vacuum pump.

### Modified Example 2: Multivariate Abnormality Detection Model Construction

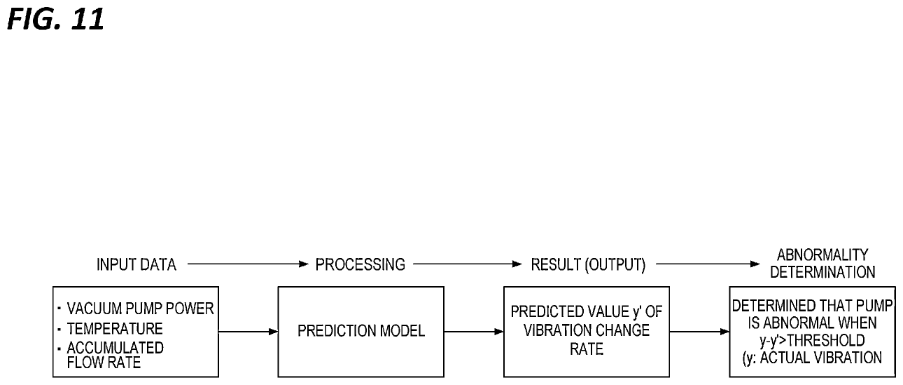

As illustrated in FIG. 11, a prediction model may be created using the power of the vacuum pump, the temperature of the vacuum pump, and the cumulative flow rate flowing through the vacuum pump (the cumulative flow rate of a film formation gas), as explanatory variables, and a model that outputs a vibration change rate (predicted value) as a result may be constructed.

Specifically, in the analysis target step, a prediction model such as a multiple regression or autoregression rule is created with the vibration change rate (predicted value) as a target variable, and the power, the temperature, and the cumulative flow rate of the vacuum pump as explanatory variables. Then, the difference between an actual vibration change rate y and a predicted value y′ of a vibration change rate is calculated. This difference (y-y′) is an example of an index of a divergence degree, and then the degree of abnormality of the vacuum pump may be evaluated. For example, when the difference (y-y′) is greater than a predetermined threshold, it may be determined that the vacuum pump is abnormal.

When sensor information of each of the vibration sensor and the temperature sensor cannot be acquired, a part of noise, such as power fluctuations, by which the abnormality of the vacuum pump is determined, may be excluded from stable vibration data. Thus, the accuracy of abnormality determination of the vacuum pump may be improved as compared to in the conventional method.

The substrate processing apparatus disclosed in this specification is not limited to the batch-type heat treatment apparatus. For example, the substrate processing apparatus 10 may be a single-wafer type apparatus that processes wafers one by one. Also, the substrate processing apparatus 10 may be a semi-batch type apparatus that processes several substrates at once. The semi-batch type apparatus may be an apparatus in which a plurality of wafers disposed around the rotation center line of a rotary table is rotated together with the rotary table, and passes through regions to which different gases are supplied, in sequence.

The substrate processing apparatus is not limited to a film formation apparatus, but may be an apparatus capable of processing substrates, such as an etching device or a sputtering device. Also, the substrate processing apparatus 10 is not limited to an apparatus that processes substrates by using plasma, but may be an apparatus that processes substrates without using plasma.

According to an aspect, it is possible to accurately determine a predictive sign of abnormality of the vacuum pump.

From the foregoing content, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

What is claimed is:

1. A state determination method comprising:
(a) acquiring vibration data from a sensor that detects vibration of a vacuum pump provided in a substrate processing apparatus that performs a substrate processing based on a recipe including a plurality of steps, in a specific step among the plurality of steps;
(b) calculating a vibration power spectrum of a predetermined frequency based on the vibration data, and calculating a vibration change feature amount of a predetermined frequency band from the vibration power spectrum of the predetermined frequency;
(c) calculating, in the specific step, a first divergence degree indicating a degree of divergence between a normal vibration feature amount calculated in advance through execution of (b), and the vibration change feature amount of the predetermined frequency band subsequently calculated in (b), based on the vibration data acquired from the sensor that detects the vibration of the vacuum pump at the time of replacement or a brand-new vacuum pump; and
(d) outputting a warning about a state of the vacuum pump when the first divergence degree is equal to or greater than a first threshold set in advance.

2. The state determination method according to claim 1, wherein the vibration change feature amount of the predetermined frequency band includes a vibration change feature amount of an entire frequency band, and a vibration change feature amount of each frequency band obtained when the entire frequency band is divided into a plurality of frequency bands,
in (c), a first divergence degree of the entire frequency band is calculated, which indicates a degree of divergence between a normal vibration feature amount of the entire frequency band calculated in advance through execution of (b), and a vibration change feature amount of the entire frequency band calculated in (b), and a first divergence degree of each frequency band is calculated, which indicates a degree of divergence between a normal vibration feature amount of each frequency band calculated in advance through execution of (b), and a vibration change feature amount of each frequency band calculated in (b), and
in (d), the warning about the state of the vacuum pump is output when the first divergence degree of the entire frequency band is equal to or greater than a first threshold set in advance for the entire frequency band, or when the first divergence degree of each frequency band is equal to or greater than a first threshold set in advance for each frequency band.

3. The state determination method according to claim 1, further comprising:
(e) calculating a second divergence degree indicating a degree of divergence between a vibration power spectrum of a predetermined frequency band calculated based on the vibration data acquired during a previous substrate processing performed by the substrate processing apparatus, and a vibration power spectrum of the predetermined frequency band calculated based on the vibration data acquired during a present substrate processing performed by the substrate processing apparatus; and
(f) outputting a warning about the state of the vacuum pump when the second divergence degree is equal to or greater than a second threshold set in advance.

4. The state determination method according to claim 3, wherein the vibration power spectrum of the predetermined frequency band includes a vibration power spectrum of an entire frequency band, and a vibration power spectrum of each separate predetermined frequency band obtained when the entire frequency band is divided into a plurality of frequency bands, and
in (e), a second divergence degree of the entire frequency band is calculated, which indicates a degree of divergence between a vibration power spectrum of the entire frequency band calculated based on the vibration data acquired during a previous substrate processing performed by the substrate processing apparatus in (b), and a vibration power spectrum of the entire frequency band calculated based on the vibration data acquired during a present substrate processing performed by the substrate processing apparatus in (b), and a second divergence degree of the predetermined frequency band is calculated, which indicates a degree of divergence between a vibration power spectrum of the predetermined frequency band calculated based on the vibration data acquired during the previous substrate processing performed by the substrate processing apparatus in (b), and a vibration power spectrum of the predetermined frequency band calculated based on the vibration data acquired during the present substrate processing performed by the substrate processing apparatus in (b), and
in (f), the warning about the state of the vacuum pump is output when the second divergence degree of the entire frequency band is equal to or greater than a second threshold set in advance for the entire frequency band, or when the second divergence degree of each separate predetermined frequency band is equal to or greater than a second threshold set in advance for each frequency band.

5. The state determination method according to claim 1, wherein the specific step includes a step during which the vacuum pump is idle, and a step of reducing a pressure of a processing container in which the substrate processing is performed, from an atmospheric pressure to a predetermined pressure.

6. The state determination method according to claim 1, wherein in (a), in the specific step, temperature data is acquired from a sensor that detects a temperature of the vacuum pump, together with the vibration data, and
in (b), the vibration power spectrum of the predetermined frequency is calculated based on the vibration data remaining after exclusion of the vibration data corresponding to the temperature data falling outside a preset temperature range in the temperature data acquired in (a).

7. The state determination method according to claim 1, wherein the calculated vibration power spectrum of the predetermined frequency is divided into vibration power spectra of unit frequencies for each substrate processing, and the divided vibration power spectra are visualized and displayed on a two-dimensional map having a unit frequency and a substrate processing identification number as two axes.

8. The state determination method according to claim 7, wherein the vibration change feature amounts between the substrate processings calculated from the divided vibration power spectra are visualized and displayed on a two-dimensional map having a value corresponding to the unit frequency and a substrate processing identification number, as two axes.

9. A monitoring device comprising:
(a) an acquisition circuitry configured to acquire vibration data from a sensor that detects vibration of a vacuum pump provided in a substrate processing apparatus that performs a substrate processing based on a recipe including a plurality of steps, in a specific step among the plurality of steps;
(b) a pre-processing circuitry configured to calculate a vibration power spectrum of a predetermined frequency based on the vibration data, and calculate a vibration change feature amount of a predetermined frequency band from the vibration power spectrum of the predetermined frequency;
(c) a calculation circuitry configured to calculate, in the specific step, a first divergence degree indicating a degree of divergence between a normal vibration feature amount calculated in advance by the pre-processing circuitry and the vibration change feature amount of the predetermined frequency band subsequently calculated by the pre-processing circuitry, based on the vibration data acquired from the sensor that detects the vibration of the vacuum pump at the time of replacement or a brand-new vacuum pump; and
(d) a display control circuitry configured to output a warning about a state of the vacuum pump when the first divergence degree is equal to or greater than a first threshold set in advance.
